(19) United States
(12) Patent Application Publication
(10) Pub. No.: US 2008/0106297 A1
(43) Pub. Date: May 8, 2008

(54) SLEW RATE CONTROLLED CIRCUITS

(75) Inventor: Che-Yuan Jao, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/933,451

(22) Filed: Nov. 1, 2007

Related U.S. Application Data
(60) Provisional application No. 60/864,166, filed on Nov. 3, 2006.

(51) Int. Cl. H03K 19/00; H03K 19/0185

(52) U.S. Cl. 326/27; 326/83

(57) ABSTRACT

A slew rate controlled output buffer. The slew rate controlled output buffer comprises a pre-driver circuit having a data input node and a data output node and a driver circuit coupled to the output node of the pre-driver circuit. The pre-driver circuit comprises a plurality of inverters connected in parallel, each having an input terminal coupled to the input node and an output terminal coupled to the output node, wherein at least one of the inverters is selectively disabled by a slew rate control signal via a slew rate controller. The driver circuit is driven by an output signal of the pre-driver circuit.

This application claims the benefit of U.S. Provisional Application No. 60/864,166, filed on Nov. 3, 2006, which is incorporated herein by reference.

### BACKGROUND OF THE INVENTION

1. Field of the Invention

The invention relates to semiconductor integrated circuits and, in particular, to a slew rate controlled circuit in semiconductor integrated circuit.

2. Description of the Related Art

An output buffer of a semiconductor device drives internal signals via an output terminal. A slew rate of an output buffer represents how quickly a voltage level of an output signal changes from one data state to another. A rate of voltage change is defined as slew rate of an output buffer.

The slew rate of a driver is usually controlled by adjusting a pre-driver circuit. The pre-driver is a circuit between the core circuits and a final output driver and adjusts the timing and the driving capability to the final I/O output stage such that required I/O specifications are met. A fast pre-driver reduces a propagation time for data from the chip core to the output driver but generates a sharp current spike. When a number of buffers switch simultaneously, the current spike injects noise into a power supply. Thus, it is essential to balance noise sensitivity and slew rates and propagation delays.

FIGS. 1A and 1B are respectively a circuit diagram of a conventional output buffer with controlled slew rate and a schematic diagram of switching characteristics of the output buffer. In FIG. 1A, the output buffer 100 comprises a pull-up network NP and a pull-down network NN coupled to an output node O. The pull-up network NP comprises PMOS transistors MPIO₁, MPIO₂, and MPIO₃ coupled between a supply voltage Vcc and the output node O. A gate of the PMOS transistor MPIO₁ receives a data signal DP and is coupled to a ground via a capacitor CP. A first RC delay DP1 is coupled between a gate of the PMOS transistor MPIO₂ and that of the PMOS transistor MPIO₁ and a second RC delay DP2 coupled between a gate of the PMOS transistor MPIO₃ and that of the PMOS transistor MPIO₂. The pull-down network NN comprises NMOS transistors MNIO₁, MNIO₂, and MNIO₃ coupled between a ground GND and the output node O. A gate of the NMOS transistor MNIO₁ receives a data signal DN and is coupled to a ground via a capacitor CN. A third RC delay DN1 is coupled between a gate of the NMOS transistor MNIO₂ and that of the NMOS transistor MNIO₁ and a fourth RC delay DN2 coupled between a gate of the NMOS transistor MNIO₃ and that of the NMOS transistor MNIO₂. As shown in FIG. 1B, since both turn-on and turn-off of the pull-up and pull-down networks are gradual, some overlap occurs when both NMOS and PMOS transistors are both partially on. FIG. 1C is a detailed circuit diagram of the conventional output buffer in FIG. 1A. In FIG. 1C, MOS devices are used as capacitors and transmission gates as resistors.

FIG. 2 is a circuit diagram showing how slew rate is adjusted by controlling loading on pre-driver output. In FIG. 2, a pre-driver drives gates of PMOS and NMOS transistors MP1 and MN1 of a driver. A plurality of capacitors is selectively connected to the gates of the of PMOS and NMOS transistors MP1 and MN1 via a plurality of switches. Loading on the pre-driver output can be controlled by controlling the switches.

Though slew rate of the conventional output buffers in FIGS. 1A and 2 can be controlled, a large area, due to the passive resistors and capacitors, is required. As a result, chip cost of the integrated circuits therein is also increased.

### BRIEF SUMMARY OF THE INVENTION

An embodiment of a slew rate controlled output buffer comprises a pre-driver circuit having a data input node and a data output node and a driver circuit coupled to the output node of the pre-driver circuit. The pre-driver circuit comprises a buffer coupled between the input and output nodes and a tri-state buffer coupled between the input and output nodes and controlled by a slew rate control signal. The driver circuit is driven by an output signal of the pre-driver circuit.

An embodiment of a slew rate controlled circuit comprises a pull-up network and a pull-down network. The pull-up network comprises first and second PMOS transistors. The first PMOS transistor has a gate coupled to a data input terminal of the slew rate controlled circuit, a source, and a drain. The second PMOS transistor has a gate coupled to the data input terminal via a first slew rate controller, and a source and a drain respectively coupled to the source and the drain of the first PMOS transistor. The pull-down network comprises first and second NMOS transistors. The first NMOS transistor comprises a gate coupled to the data input terminal, a source, and a drain. The second NMOS transistor has a gate coupled to the data input terminal via a second slew rate controller, and a source and a drain respectively coupled to the source and the drain of the first NMOS transistor. The second PMOS and NMOS transistors are selectively turned off by the slew rate controller according to a slew rate control signal.

An embodiment of a slew rate controlled output buffer comprises a pre-driver circuit having a data input node and a data output node and a driver circuit coupled to the output node of the pre-driver circuit. The pre-driver circuit comprises a plurality of inverters connected in parallel, each comprising an input terminal coupled to the input node and an output terminal coupled to the output node, wherein at least one of the inverters is selectively disabled by a slew rate control signal via a slew rate controller. The driver circuit is driven by an output signal of the pre-driver circuit.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1A and 1B are respectively a circuit diagram of a conventional output buffer with controlled slew rate and a schematic diagram of switching characteristics of the output buffer;

FIG. 1C is a detailed circuit diagram of the conventional output buffer in FIG. 1A;

FIG. 2 is a circuit diagram showing how slew rate is adjusted by controlling loading on pre-driver output;

FIG. 3A is a block diagram of a slew rate controlled output buffer according to an embodiment of the invention;

FIGS. 3B and 3C are respectively circuit diagrams of a voltage mode driver and a current mode driver;

FIG. 4 is a detailed block diagram of the slew rate controlled output buffer according to an embodiment of the invention;

FIG. 5A is a circuit diagram of the pre-driver cell in FIG. 4;

FIG. 5B is a schematic diagram of a signal generator generating the complement of the slew rate control signals SLEW<0, m>;

FIG. 5C is schematic diagram showing output waveforms of the pre-driver cell in FIG. 5A;

FIG. 6 is a circuit diagram of the pre-driver cell in FIG. 4;

FIGS. 7A and 7B are respectively a schematic diagram and a circuit diagram of a slew rate controlled NOR gate according to an embodiment of the invention;

FIG. 7C is a schematic diagram of a signal generator generating the complement of the slew rate control signals SLEW<0, m>;

FIGS. 8A and 8B are respectively a schematic diagram and a circuit diagram of a slew rate controlled NAND gate according to an embodiment of the invention; and

FIG. 8C is a schematic diagram of a signal generator generating the complement of the slew rate control signals SLEW<0, m>.

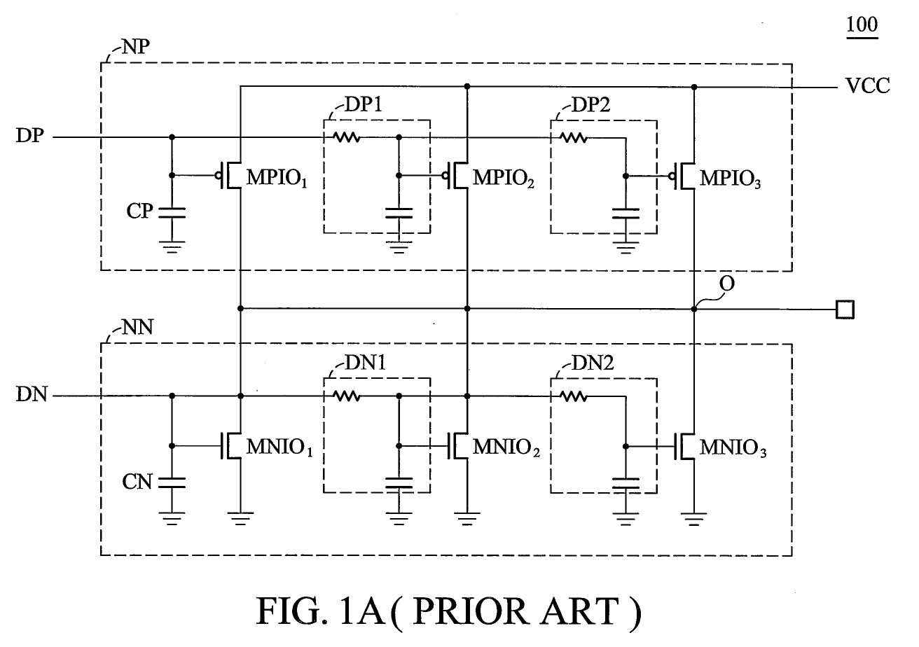

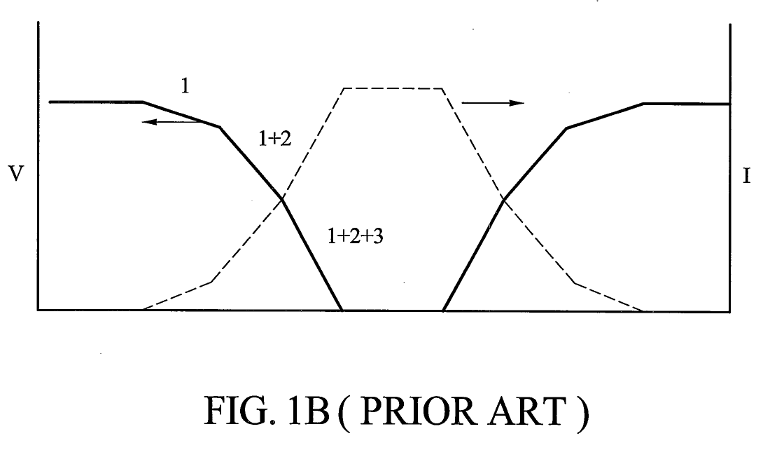

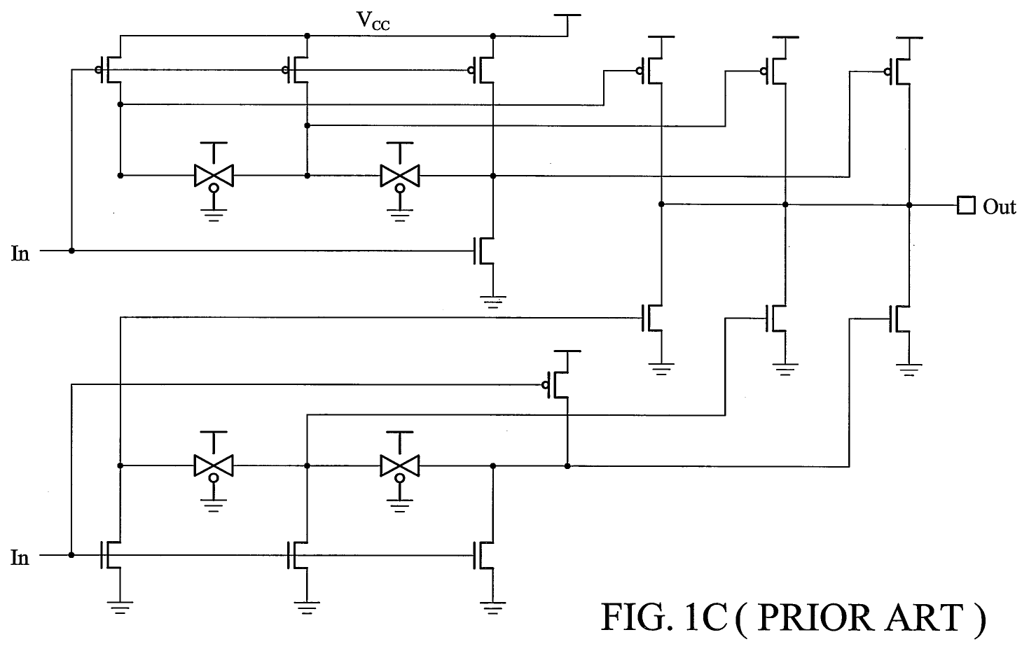

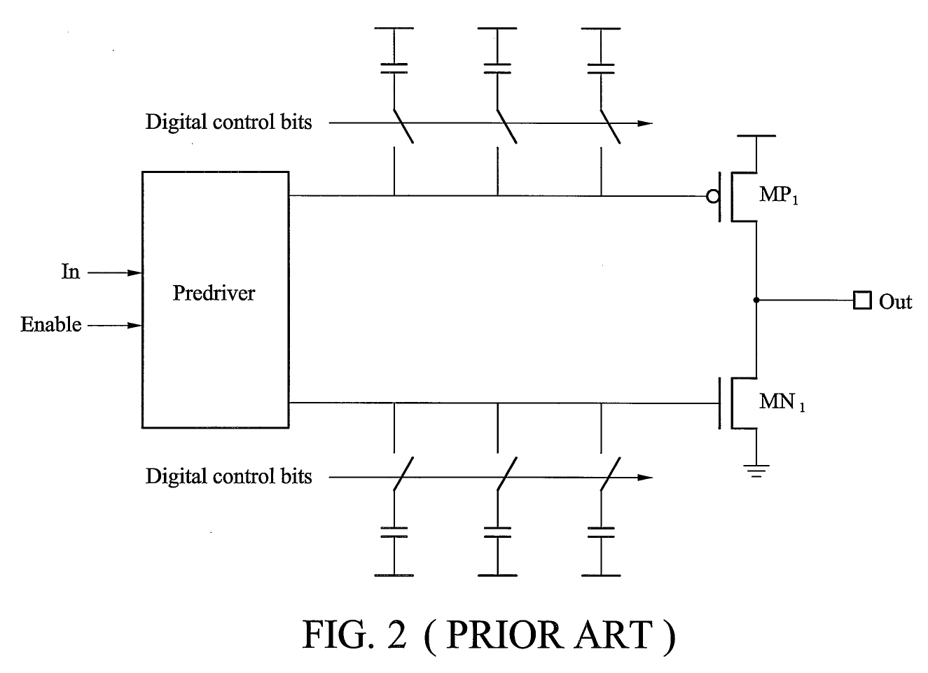

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

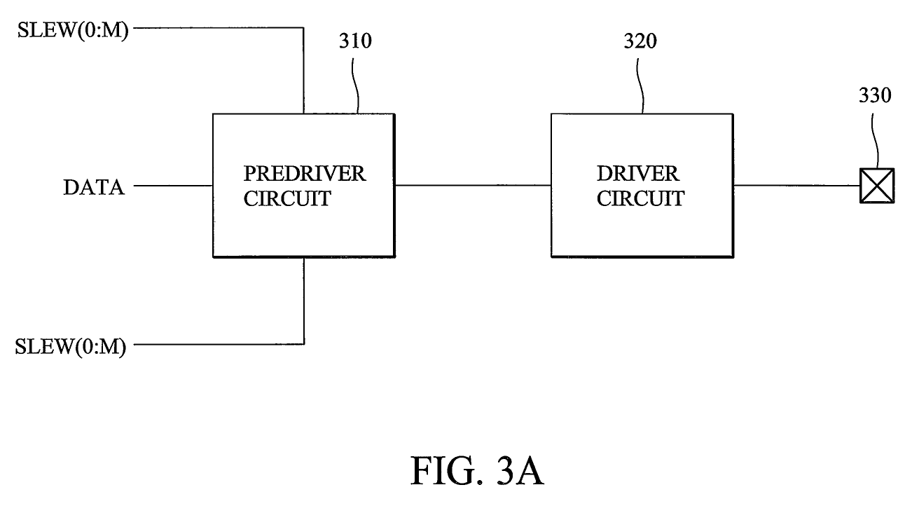

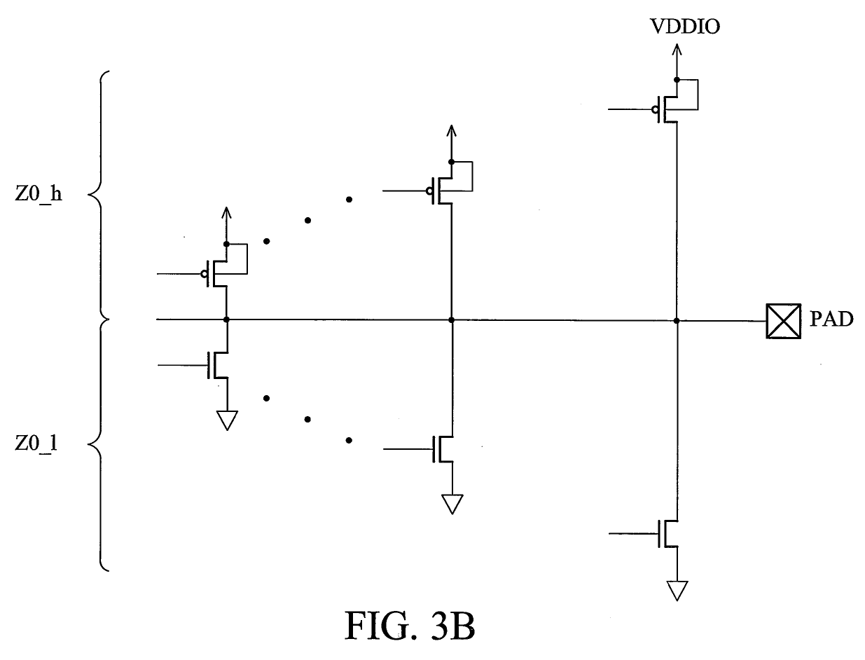

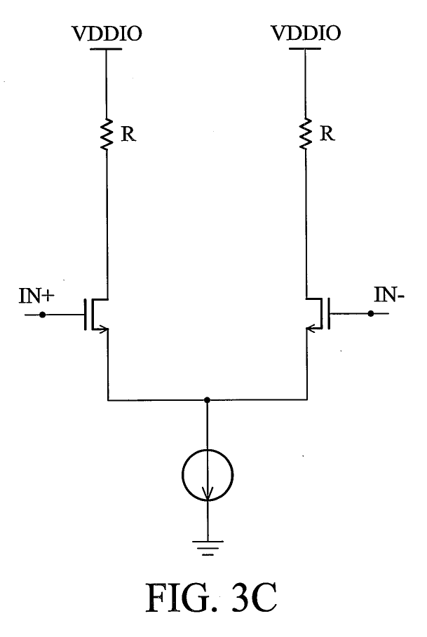

FIG. 3A is a block diagram of a slew rate controlled output buffer according to an embodiment of the invention. In FIG. 3A, the slew rate controlled output buffer 300 comprises a pre-driver circuit 310, a driver circuit 320, and a pad 330. The pre-driver circuit 310 receives an input data signal, pull-up slew rate control signals PSLEW<0, m>, and pull-down slew rate control signals NSLEW<0, m>. The driver circuit 320 is coupled to the pre-driver circuit 310 and driven by an output signal thereof. The pad 330 is coupled to the driver circuit 320 and driven by an output signal thereof. The pre-driver circuit 310 adjusts a slew rate of the output signal of the driver circuit 320 according to the pull-up slew rate control signals PSLEW<0, m> and the pull-down slew rate control signals NSLEW<0, m>. FIGS. 3B and 3C are respectively circuit diagrams of a voltage mode driver and a current mode driver. In FIG. 3B, the voltage mode driver comprises a pull-up network ZΦ_h connected between a supply voltage VDDIO and a pad PAD and a pull-down network ZΦ_l connected between the pad PAD and a ground GND. The pull-up network ZΦ_h comprises PMOS transistors each having a source connected to the supply voltage VDDIO and a drain connected to the pad PAD. The pull-down network ZΦ_l comprises NMOS transistors each having a source connected to the ground GND and a drain connected to the pad PAD. Gates of the PMOS and NMOS transistors are driven by the pre-driver circuit 310 shown in FIG. 3A. In FIG. 3C, the current mode driver comprises a pair of NMOS transistors having sources commonly connected, drains coupled to a supply voltage VDDIO via load devices R, and gates driven by the pre-driver circuit 310 shown in FIG. 3A, and a current source coupled between the sources and a ground GND.

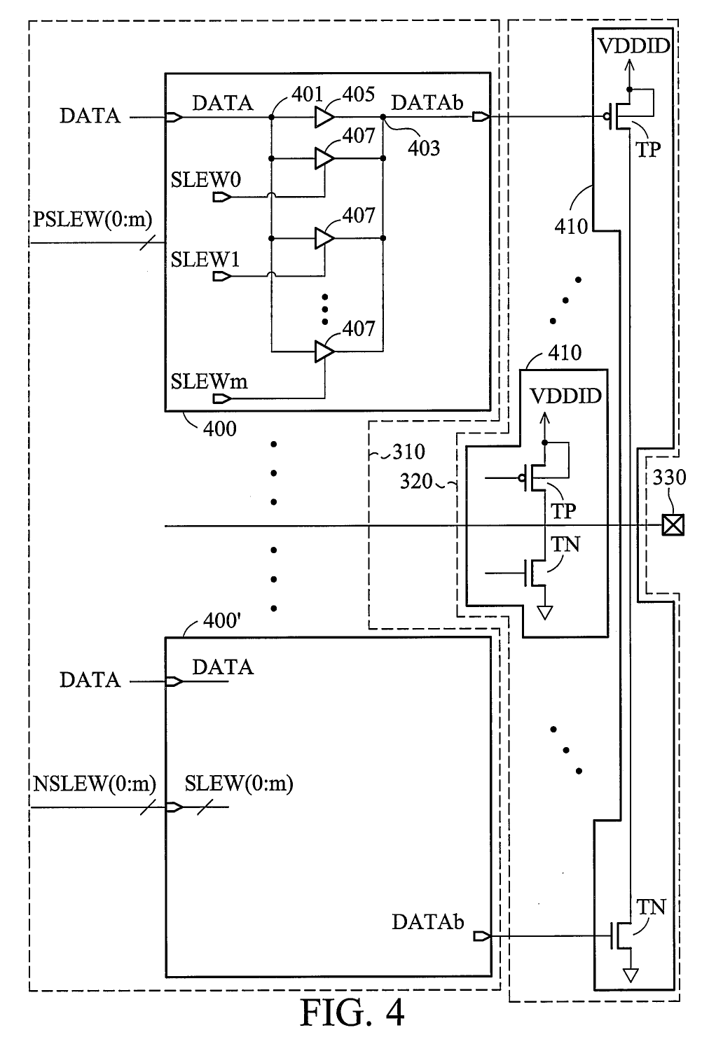

FIG. 4 is a detailed block diagram of the slew rate controlled output buffer according to an embodiment of the invention. The pre-driver circuit 310 comprises a plurality of pull-up pre-driver cells 400 and a plurality of pull-down pre-driver cells 400′. Each of the pull-up pre-driver cells 400 has a data input node 401 and a data output node 403 and receives an input data signal DATA. In addition, each of the pull-up pre-driver cells 400 comprises a buffer 405 and a plurality of tri-state buffers 407 coupled between the input and output nodes 401 and 403. Each of the tri-state buffers 407 are selectively disabled according to one of the pull-up slew rate control signals PSLEW<0, m>, i.e. SLEW0, SLEW1, . . . , or SLEWm. Each of the pull-down pre-driver cells 400′ has the same elements as the pull-up pre-driver cells 400 and only differs in that each of the pull-down pre-driver cells 400′ receives the pull-down slew rate control signals NSLEW<0, m> rather than the pull-up slew rate control signals PSLEW<0, m>. Each of the pull-up and pull-down pre-driver cells 400 and 400′ provides an output signal DATAb. The driver circuit 320 comprises a plurality of inverters 410 each comprising a PMOS transistor TP and an NMOS transistor TN connected in series between a supply voltage VDDIO and a ground GND. Each gate of the PMOS transistors TP is connected to the data output node 403 of a corresponding pull-up pre-driver cell 400 and each gate of the NMOS transistors TN connected to the data output node 403′ of a corresponding pull-down pre-driver cell 400′. Drains of the PMOS and NMOS transistor TP and TN are commonly connected to the pad 330.

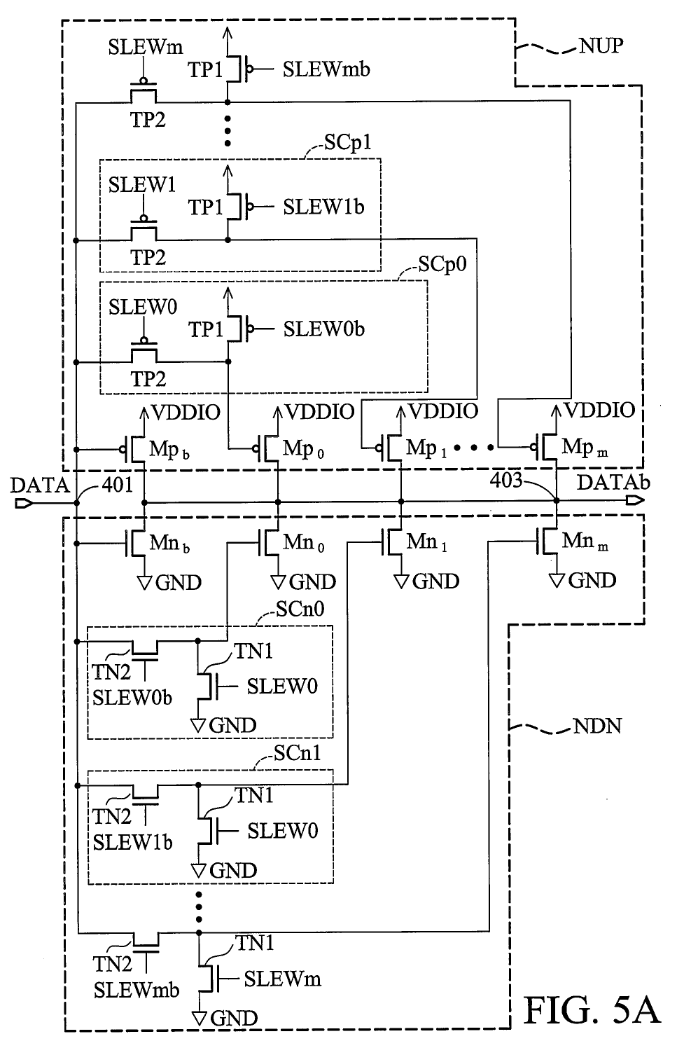

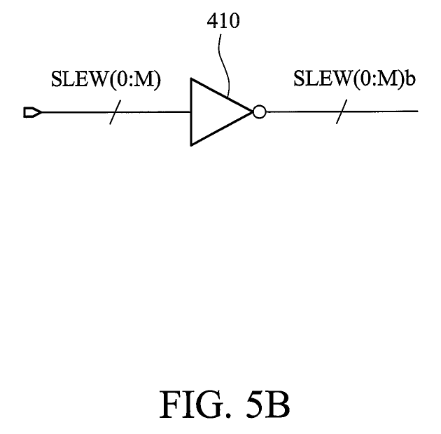

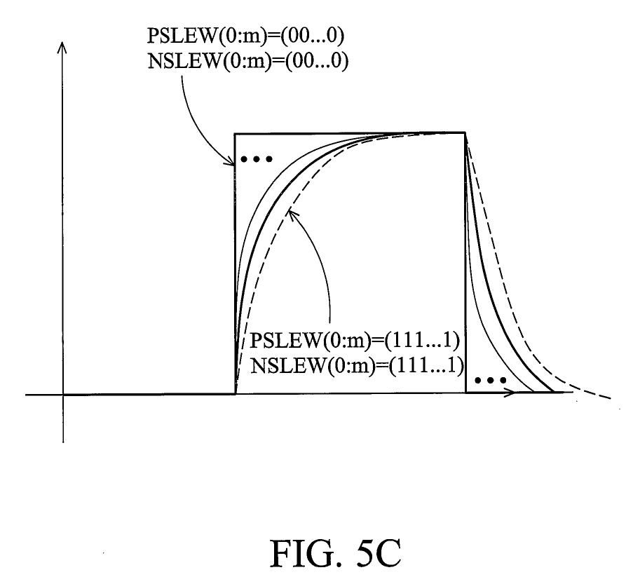

FIG. 5A is a circuit diagram of the pre-driver cell in FIG. 4. The pre-driver cell comprises a pull-up network NUP connected between a supply voltage VDDIO and the data output node 403 and a pull-down network NDN connected between the data output node 403 and a ground GND. The pull-up network NUP comprises PMOS transistors Mpb, Mp0, Mp1, . . . , and Mpm, each having a source connected to the supply voltage VDDIO and a drain connected to the data output node 403. The pull-down network NDN comprises NMOS transistors Mnb, Mn0, Mn1, . . . , and Mnm, each having a source connected to the ground GND and a drain connected to the data output node 403. Gates of the PMOS and NMOS transistors Mpb and Mnb are connected to the data input node 401. Gates of the PMOS and NMOS transistors Mp0 and Mn0 are respectively coupled to the data input node 401 via slew rate controllers SCp0 and SCn0. Gates of the PMOS and NMOS transistors Mp1 and Mn1 are respectively coupled to the data input node 401 via slew rate controllers SCp1 and SCn1, and so on. Each of the slew rate controllers SCp0, SCp1, . . . , SCpm in the pull-up network NUP comprises a first PMOS transistor TP1 coupled between the gate of a corresponding PMOS transistor (Mp0, Mp1, . . . , or Mpm) and a power rail VDDIO, and a second PMOS transistor TP2 coupled between the input node 401 and a drain of the first PMOS transistor TP1. Each of the first and second PMOS transistors TP1 and TP2 is respectively controlled by a complement of the slew rate control signal (SLEW0b, SLEW0b, . . . , or SLEW0b) and the slew rate control signal (SLEW0, SLEW0, . . . , or SLEW0). Similarly, each of the slew rate controllers SCn0, SCn1, . . . , SCnm in the pull-down network NDN comprises a first NMOS transistor TN1 coupled between the gate of a corresponding NMOS transistor (Mn0, Mn1, . . . , or Mnm) and a ground GND, and a second NMOS transistor TN2 coupled between the input node 401 and a drain of the first NMOS transistor TN1. Each of the first and second NMOS transistors TN1 and TN2 are respectively controlled by the slew rate control signal (SLEW0, SLEW0, . . . , or SLEW0) and the complement of the slew rate control signal (SLEW0b, SLEW0b, . . . , or SLEW0b). FIG. 5B is a schematic diagram of a signal generator generating the complement of the slew rate control signals SLEW<0, m>. More specifically, the signal generator is an inverter 410. The inverter 410 receives the slew rate control signals SLEW<0, m> and generates the complement the slew rate control signals SLEW<0, m>b of the slew rate control signals SLEW<0, m>.

FIG. 5C is a schematic diagram showing output waveforms of the pre-driver cell in FIG. 5A. When the slew rate control signals SLEW<0, m> are set to all 0, <000 . . . 0> for m+1 bits, all slew rate controllers are disabled. All PMOS transistors Mpb, Mp0, Mp1, . . . and Mpm and all NMOS transistors Mnb, Mn0, Mn1, . . . , and Mnm operate as an inverter in response to the data input signal DATA. This setting renders the sharpest slew rate since all PMOS transistors are used for pull-up to the supply voltage VDDIO and all NMOS transistors are used to pull-down to the ground GND. Conversely, when the slew rate control signals SLEW<0, m> are set to all 1, <111 . . . 1> for m+1 bits, all slew rate controllers are enabled. Only the PMOS transistor Mpb and the NMOS transistor Mnb are still used for pull-up and pull-down, respectively. In addition, the disabled PMOS transistors Mpb, Mp0, Mp1, . . . , and Mpm and NMOS transistors Mnb, Mn0, Mn1, . . . , and Mnm can be used as additional loading and slew rate is thus further slowed.

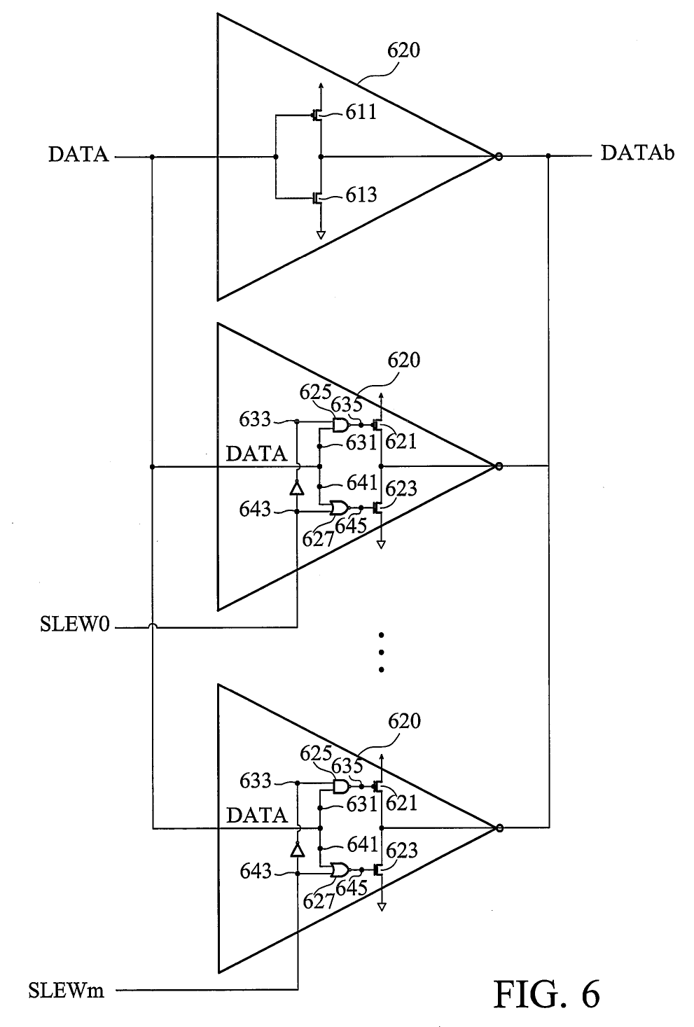

FIG. 6 is another circuit diagram of the pre-driver cell in FIG. 4, comprising an inverter 610 and a plurality of tri-state buffers 620 coupled between the data input node 401 and the data output node 403. The inverter 610 comprises a PMOS transistor 611 and an NMOS transistor 613 connected in series between a supply voltage VDDIO and a ground. Gates and drains of the PMOS transistor 611 and the NMOS transistor 613 are respectively connected to the data input node 401 and the data output node 403. Each of the tri-state buffers 620 comprises an inverter having a pull-up transistor 621 and a pull-down transistor 623, a NAND gate 625 and a NOR gate 627. Drains of the pull-up transistor 621 and the pull-down transistor 623 are connected to the data output node 403. The NAND gate 625 has a first input terminal 631 coupled to the data input node 401, a second input terminal 633, and an output terminal 635 coupled to a gate of the pull-up transistor 621. The NOR gate 627 has a first input terminal 641 coupled to the data input node 401, a second input terminal 643, and an output terminal 645 coupled to a gate of the pull-down transistor 623. The second input terminal 643 of the NOR gate 627 receives one of the slew rate control signals SLEW<0, m> and an inverter is coupled between the second terminals of the NOR gate 627 and the NAND gate 625.

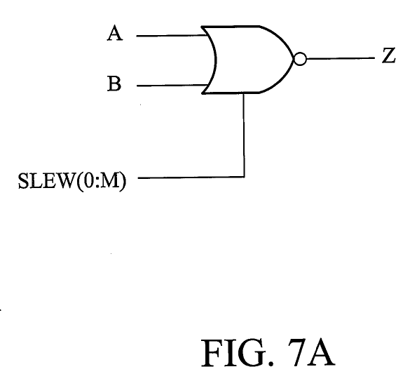

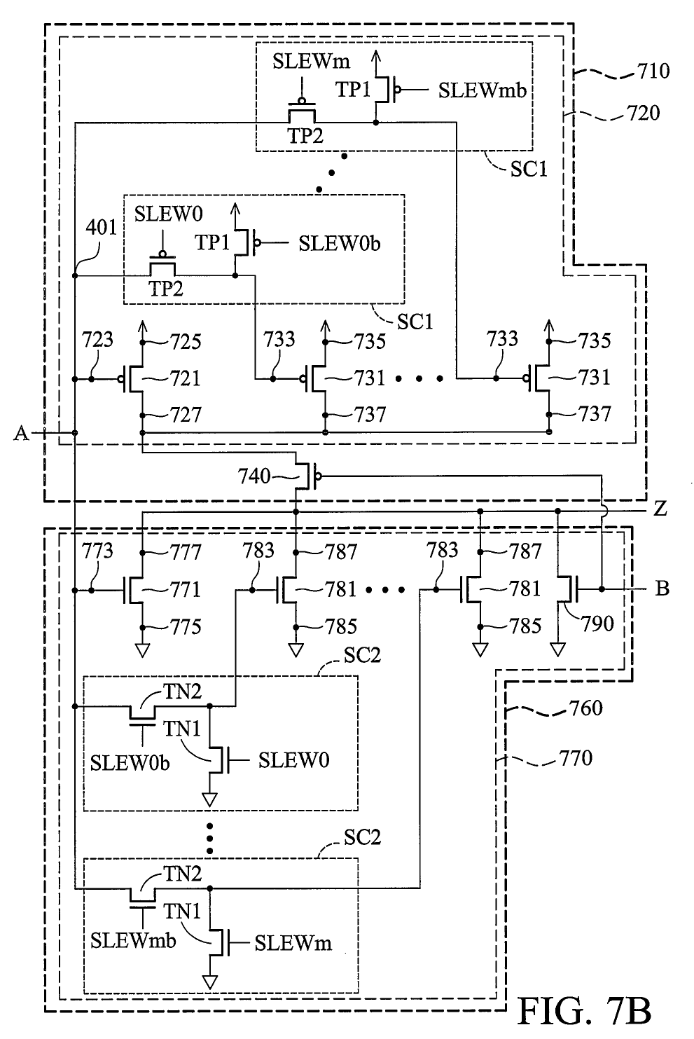

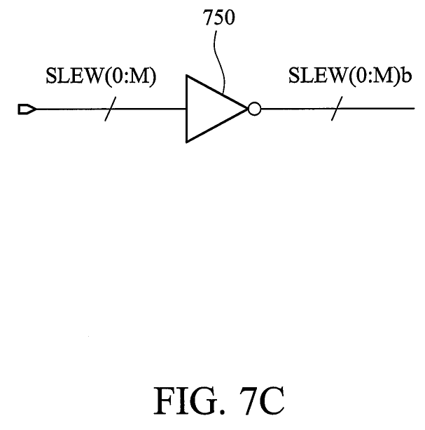

FIGS. 7A and 7B are respectively a schematic diagram and a circuit diagram of a slew rate controlled NOR gate according to an embodiment of the invention. The slew rate controlled NOR gate comprises a pull-up network 710 and a pull-down network 760. The pull-up network 710 comprises a PMOS group 720 and a PMOS transistor 740 connected in series between a supply voltage VDDIO and an output node Z. The PMOS group 740 comprises a first PMOS transistor 721 having a gate 723 coupled to a data input terminal A of the slew rate controlled NOR gate, a source 725 coupled to a supply voltage VDDIO, and a drain 727 and second PMOS transistor 731 each having a gate 733 coupled to the data input terminal A via a first slew rate controller SC1, and a source 735 and a drain 737 respectively coupled to the source 725 and the drain 727 of the first PMOS transistor 721. Each of the first slew rate controllers SC1 comprises a PMOS transistor TP1 coupled between the gate of the second PMOS transistor 731 and a first power rail VDDIO, and a PMOS transistor TP2 coupled between the input node 401 and a drain of the PMOS transistor TP1. Gates of the PMOS transistors TP1 and TP2 are respectively controlled by a complement of the slew rate signal (SLEW0b, SLEW1b, . . . , or SLEWmb) and the slew rate signal (SLEW0, SLEW1, . . . , or SLEWm). The pull-down network 760 comprises an NMOS group 770 and an NMOS transistor 790 connected in parallel between a ground GND and the output node Z. The NMOS group 770 comprises a first NMOS transistor 771 having a gate 773 coupled to a data input terminal A of the slew rate controlled NOR gate, a source 775 coupled to the ground GND, and a drain 777, and second NMOS transistor 781 each having a gate 783 coupled to the data input terminal A via a second slew rate controller SC2, and a source 785 and a drain 787 respectively coupled to the source 775 and the drain 777 of the first NMOS transistor 771. Each of the first slew rate controllers SC2 comprises an NMOS transistor TN1 coupled between the gate of the second NMOS transistor 781 and the ground GND, and an NMOS transistor TN2 coupled between the input node 401 and a drain of the NMOS transistor TN1. Gates of the NMOS transistors TN1 and TN2 are respectively controlled by the slew rate signal (SLEW0, SLEW1, . . . , or SLEWm) and the complement of the slew rate signal (SLEW0b, SLEW1b, . . . , or SLEWmb). FIG. 7C is a schematic diagram of a signal generator generating the complement of the slew rate control signals SLEW<0, m>. More specifically, the signal generator is an inverter 750. The inverter 750 receives the slew rate control signals SLEW<0, m> and generates the complement the slew rate control signals SLEW<0, m>b of the slew rate control signals SLEW<0, m>

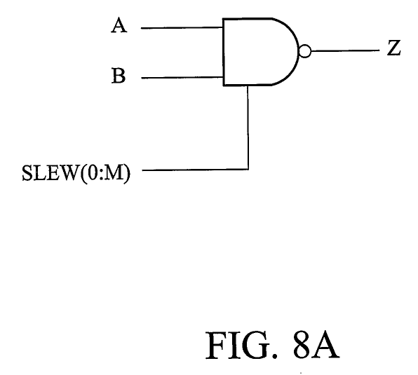

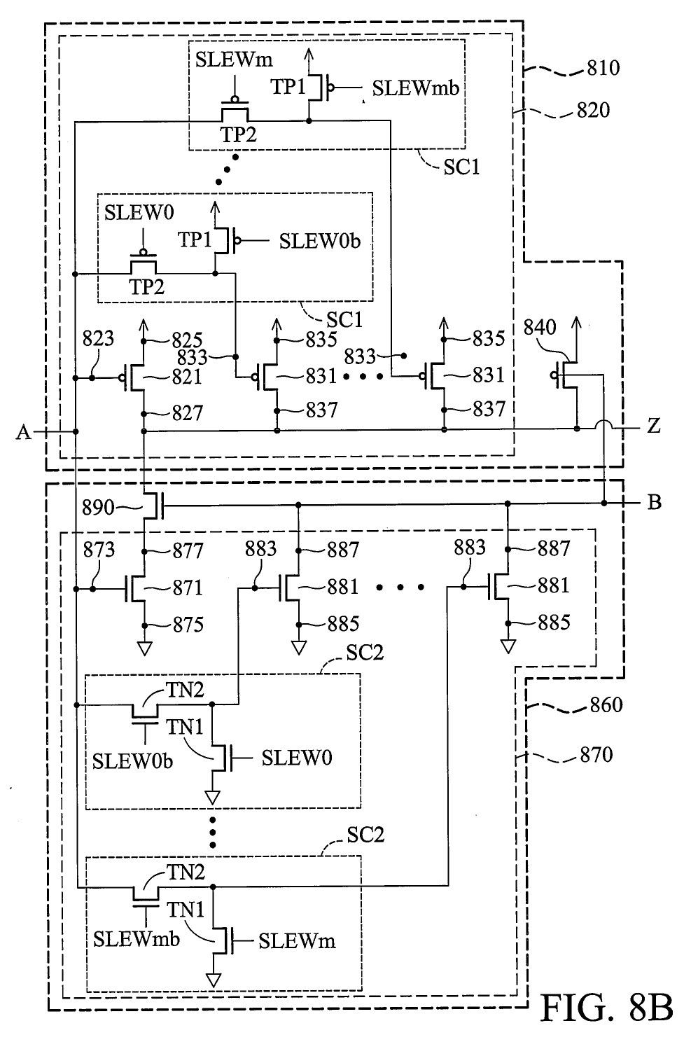

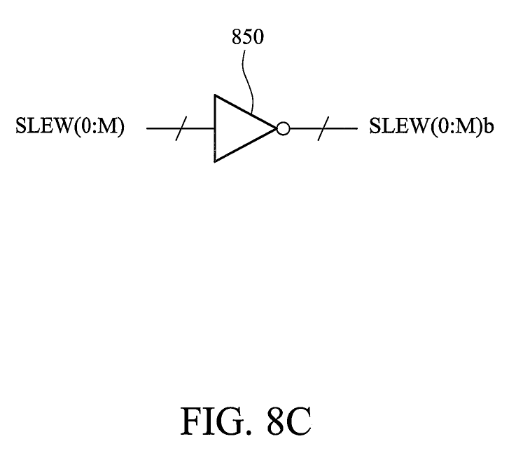

FIGS. 8A and 8B are respectively a schematic diagram and a circuit diagram of a slew rate controlled NAND gate according to another embodiment of the invention. The slew rate controlled NAND gate comprises a pull-up network 810 and a pull-down network 860. The pull-up network 810 comprises a PMOS group 820 and a PMOS transistor 840 connected in parallel between a supply voltage VDDIO and an output node Z. The PMOS group 820 comprises a first PMOS transistor 821 having a gate 823 coupled to a data input terminal A of the slew rate controlled NAND gate, a source 825 coupled to a supply voltage VDDIO, and a drain 827, and second PMOS transistor 831 each having a gate 833 coupled to the data input terminal A via a first slew rate controller SC1, and a source 835 and a drain 837 respectively coupled to the source 825 and the drain 827 of the first PMOS transistor 821. Each of the first slew rate controllers SC1 comprises a PMOS transistor TP1 coupled between the gate of the second PMOS transistor 831 and a first power rail VDDIO, and a PMOS transistor TP2 coupled between the input node 401 and a drain of the PMOS transistor TP1. Gates of the PMOS transistors TP1 and TP2 are respectively controlled by a complement of the slew rate signal (SLEW0b, SLEW1b, . . . , or SLEWmb) and the slew rate signal (SLEW0, SLEW1, . . . , or SLEWm). The pull-down network 860 comprises an NMOS group 870 and an NMOS transistor 890 connected in series between a ground GND and the output node Z. The NMOS group 870 comprises a first NMOS transistor 871 having a gate 873 coupled to a data input terminal A of the slew rate controlled NAND gate, a source 875 coupled to the ground GND, and a drain 877, and second NMOS transistor 881 each having a gate 883 coupled to the data input terminal A via a second slew rate controller SC2, and a source 885 and a drain 887 respectively couple to the source 875 and the drain 877 of the first NMOS transistor 871. Each of the first slew rate controllers SC2 comprises an NMOS transistor TN1 coupled between the gate of the second NMOS transistor 881 and the ground GND, and an NMOS transistor TN2 coupled between the input node 401 and a drain of the NMOS transistor TN1. Gates of the NMOS transistors TN1 and TN2 are respectively controlled by the slew rate signal (SLEW0, SLEW1, . . . , or SLEWm) and the complement of the slew rate signal (SLEW0b, SLEW1b, . . . , or SLEWmb). FIG. 8C is a schematic diagram of a signal generator generating the complement of the slew rate control signals SLEW<0, m>. More specifically, the signal generator is an inverter 850. The inverter 850 receives the slew rate control signals SLEW<0, m> and generates the complement of the slew rate control signals SLEW<0, m>b of the slew rate control signals SLEW<0, m>

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A slew rate controlled output buffer, comprising:
a pre-driver circuit having a data input node and a data output node, comprising:
a buffer coupled between the input and output nodes; and
a tri-state buffer coupled between the input and output nodes and controlled by a slew rate control signal; and
a driver circuit coupled to the output node of the pre-driver circuit and driven by an output signal thereof.

2. The slew rate controlled output buffer as claimed in claim 1, wherein the driver circuit is a voltage mode driver.

3. The slew rate controlled output buffer as claimed in claim 1, wherein the driver circuit is a current mode driver.

4. The slew rate controlled output buffer as claimed in claim 1, wherein the tri-state buffer comprises an inverter which can be disabled by the slew rate control signal.

5. The slew rate controlled output buffer as claimed in claim 4, wherein the tri-state buffer further comprises a first MOS transistor coupled between an input of the inverter and a power rail, and a second MOS transistor coupled between the input node and a drain of the first MOS transistor, wherein gates of the first and second MOS transistors are respectively controlled by the slew rate signal and a complement of the slew rate signal.

6. The slew rate controlled output buffer as claimed in claim 1, wherein the tri-state buffer comprises an inverter which can be disabled by the slew rate control signal via a combinational logic circuit.

7. The slew rate controlled output buffer as claimed in claim 6, wherein the combinational logic circuit comprises a NAND gate having a first input terminal coupled to the input node, a second input terminal and an output terminal coupled to an input terminal of a pull-up network of the inverter and a NOR gate having a first input terminal coupled to the input node, a second input terminal, and an output terminal coupled to an input terminal of a pull-down network of the inverter, wherein the second input terminals of the NOR gate and the NAND gate respectively receive the slew rate control signal and a complement of the slew rate control signal.

8. A slew rate controlled circuit, comprising:
a pull-up network, comprising:
a first PMOS transistor having a gate coupled to a data input terminal of the slew rate controlled circuit, a source, and a drain; and
a second PMOS transistor having a gate coupled to the data input terminal via a first slew rate controller, and a source and a drain respectively coupled to the source and the drain of the first PMOS transistor; and
a pull-down network, comprising:
a first NMOS transistor having a gate coupled to the data input terminal, a source, and a drain; and
a second NMOS transistor having a gate coupled to the data input terminal via a second slew rate controller, and a source and a drain respectively coupled to the source and the drain of the first NMOS transistor;
wherein the second PMOS and NMOS transistors are selectively turned off by the first and second slew rate controllers according to a slew rate control signal.

9. The slew rate controlled circuit as claimed in claim 8, wherein the first slew rate controller comprises a first MOS transistor coupled between the gate of the second PMOS transistor and a first power rail, and a second MOS transistor coupled between the input node and a drain of the first MOS transistor, wherein gates of the first and second MOS transistors are respectively controlled by a complement of the slew rate signal and the slew rate signal.

10. The slew rate controlled circuit as claimed in claim 9, wherein the second slew rate controller comprises a third MOS transistor coupled between the gate of the second NMOS transistor and a first power rail, and a fourth MOS transistor coupled between the input node and a drain of the third MOS transistor, wherein gates of the third and fourth MOS transistors are respectively controlled by the slew rate signal and the complement of the slew rate signal.

11. The slew rate controlled circuit as claimed in claim 9, wherein the slew rate controlled circuit is a NAND gate.

12. The slew rate controlled circuit as claimed in claim 9, wherein the slew rate controlled combinational logic circuit is a NOR gate.

13. An electronic system comprising the slew rate controlled circuit as claimed in claim 9.

14. A slew rate controlled output buffer, comprising:
a pre-driver circuit having a data input node and a data output node, comprising a plurality of inverters connected in parallel, each comprising an input terminal coupled to the input node and an output terminal coupled to the output node, wherein at least one of the inverters is selectively disabled by a slew rate control signal via a slew rate controller; and
a driver circuit coupled to the output node of the pre-driver circuit and driven by an output signal thereof.

15. The slew rate controlled output buffer as claimed in claim 14, wherein the driver circuit is a voltage mode driver.

16. The slew rate controlled output buffer as claimed in claim 14, wherein the driver circuit is a current mode driver.

17. The slew rate controlled output buffer as claimed in claim 14, wherein the slew rate controller comprises a first MOS transistor coupled between an input of the inverter therein and a power rail, and a second MOS transistor coupled between the input node and a drain of the first MOS transistor, wherein gates of the first and second MOS transistors are respectively controlled by the slew rate signal and a complement of the slew rate signal.

18. The slew rate controlled output buffer as claimed in claim 14, wherein the slew rate controller comprises a combinational logic circuit.

19. The slew rate controlled output buffer as claimed in claim 18, wherein the combinational logic circuit comprises a NAND gate having a first input terminal coupled to the data input node, a second input terminal and an output terminal coupled to an input terminal of a pull-up transistor of the inverter and a NOR gate having a first input terminal coupled to the data input node, a second input terminal, and an output terminal coupled to an input terminal of a pull-down transistor of the inverter, wherein the second input terminals of the NOR gate and the NAND gate respectively receive the slew rate control signal and a complement of the slew rate control signal.

20. An electronic system comprising the slew rate controlled output buffer as claimed in claim 14.
